(19) United States
(12) Patent Application Publication
(10) Pub. No.: US 2026/0262500 A1
(43) Pub. Date: Sep. 3, 2026

(54) SEMICONDUCTOR ELEMENT AND METHOD FOR MANUFACTURING SEMICONDUCTOR ELEMENT

(71) Applicant: SONY SEMICONDUCTOR SOLUTIONS CORPORATION, Kanagawa (JP)

(72) Inventor: Yoshiaki YANAGAWA, Tokyo (JP)

(73) Assignee: SONY SEMICONDUCTOR SOLUTIONS CORPORATION, Kanagawa (JP)

(21) Appl. No.: 19/164,827

(22) PCT Filed: Jan. 26, 2024
(86) PCT No.: PCT/JP2024/002374

§ 371 Date: Sep. 12, 2025

(30) Foreign Application Priority Data
Mar. 24, 2023 (JP) 2023-048328

(51) Int. Cl. H10W 42/00; H10W 70/62

(52) U.S. Cl. CPC H10W 42/121; H10W 70/62

(57) ABSTRACT

To reduce inter-wiring capacitance in a semiconductor element in which a plurality of wiring lines is formed. The semiconductor element includes a semiconductor substrate, an insulating film, a protective film, a predetermined number of wiring lines, and a covering void. In this semiconductor element, the insulating film covers a predetermined surface of the semiconductor substrate. In addition, in the semiconductor element, the protective film covers the insulating film. In addition, in the semiconductor element, the predetermined number of wiring lines are formed in the protective film. In addition, in the semiconductor element, the covering void covers each of the wiring lines in the protective film.

### TECHNICAL FIELD

The present technology relates to a semiconductor element. Specifically, the present technology relates to a semiconductor element in which a plurality of wiring lines is formed, and a method for manufacturing the semiconductor element.

### BACKGROUND ART

Conventionally, wiring lines such as rewiring lines or the like have been used to electrically connect a semiconductor element and an external terminal in a wafer level chip size package (WCSP) or the like. In a case where a plurality of wiring lines is formed, potential inter-wiring capacitance is generated between the wiring lines. The inter-wiring capacitance increases as miniaturization proceeds. Since wiring delay increases as the inter-wiring capacitance increases, it is important to reduce the inter-wiring capacitance in order to implement high-speed operation. Therefore, a semiconductor element in which a void is provided between a plurality of wiring lines has been proposed (see, for example, Patent Document 1).

### CITATION LIST

### Patent Document

Patent Document 1: Japanese Patent Application Laid-Open No. H7-335747

### SUMMARY OF THE INVENTION

### Problems to be Solved by the Invention

In the conventional technology described above, inter-wiring capacitance is reduced by providing the void between the plurality of wiring lines. However, in the semiconductor element described above, it is difficult to further reduce the inter-wiring capacitance.

The present technology has been made in view of such a situation, and an object thereof is to reduce inter-wiring capacitance in a semiconductor element formed with a plurality of wiring lines.

### Solutions to Problems

The present technology has been made to solve the problems described above, and a first aspect thereof is a semiconductor element and a method for manufacturing the semiconductor element. The semiconductor element includes: a semiconductor substrate; an insulating film that covers a predetermined surface of the semiconductor substrate; a protective film that covers the insulating film; a predetermined number of wiring lines formed in the protective film; and a covering void that includes a void that covers each of the wiring lines in the protective film.

In addition, in the first aspect, an intra-insulating film void that includes a void formed in the insulating film may be further included.

In addition, in the first aspect, an intra-protective film void that includes a void formed in the protective film may be further included, the protective film may include: a first protective film that covers the insulating film; and a second protective film that covers the first protective film, and the intra-protective film void may be formed in the first protective film.

In addition, in the first aspect, an external connection terminal connected to the wiring line may be further included, and the intra-insulating film void and the intra-protective film void may be disposed so as to avoid the vicinity of the external connection terminal.

In addition, in the first aspect, the intra-insulating film void and the intra-protective film void may be disposed so as to avoid the vicinity of an end portion of the semiconductor element.

In addition, in the first aspect, the intra-insulating film void and the intra-protective film void may be preferentially disposed in a central portion of the semiconductor element.

In addition, in the first aspect, the predetermined number of wiring lines may include a pair of wiring lines that have different potentials, and the covering void may cover each of the pair of wiring lines.

In addition, in the first aspect, the covering voids may extend along the wiring lines when viewed from a direction perpendicular to the predetermined surface.

In addition, in the first aspect, contact surfaces of the wiring lines may be in contact with the insulating film, and the covering voids may cover other than the contact surface when viewed from a direction parallel to the predetermined surface.

In addition, in the first aspect, the covering void may have any one of a rectangular shape, a circular shape, and an elliptical shape when viewed from a direction perpendicular to the predetermined surface.

In addition, in the first aspect, a material of the insulating film may include any one of polyimide, silicone, acrylic, epoxy, and a spin on carbon (SOC) material.

In addition, in the first aspect, the semiconductor element may include any one of a logic circuit, a memory, an image sensor, and an interposer.

### BRIEF DESCRIPTION OF DRAWINGS

FIG. 1 is a cross-sectional view illustrating a configuration example of a semiconductor element in a first embodiment of the present technology.

FIG. 2 is an example of a cross-sectional view and a plan view of the semiconductor element in the first embodiment of the present technology.

FIG. 3 is a plan view illustrating an example of a layout of a void in the first embodiment of the present technology.

FIG. 4 is a view for describing a method for manufacturing up to formation of a pattern of rewiring lines in the first embodiment of the present technology.

FIG. 5 is a view for describing the method for manufacturing up to film formation of a protective resin film in the first embodiment of the present technology.

FIG. 6 is a view for describing the method for manufacturing up to curing in the first embodiment of the present technology.

FIG. 7 is an example of a plan view of a gray-tone mask in the first embodiment of the present technology.

FIG. 8 is another example of the plan view of the gray-tone mask in the first embodiment of the present technology.

FIG. 9 is a view for describing a relationship between transmittance and a shape of the void in the first embodiment of the present technology.

FIG. 10 is a flowchart indicating an example of the method for manufacturing the semiconductor element in the first embodiment of the present technology.

FIG. 11 is a cross-sectional view illustrating a configuration example of a semiconductor element in a second embodiment of the present technology.

FIG. 12 is a view for describing a method for manufacturing up to formation of a void in a photosensitive insulating resin film in the second embodiment of the present technology.

FIG. 13 is a view for describing the method for manufacturing up to Cu plating in the second embodiment of the present technology.

FIG. 14 is a view for describing the method for manufacturing up to lithography in the second embodiment of the present technology.

FIG. 15 is a view for describing the method for manufacturing up to formation of a pattern of rewiring lines in the second embodiment of the present technology.

FIG. 16 is a view for describing the method for manufacturing up to formation of an external connection terminal in the second embodiment of the present technology.

FIG. 17 is a block diagram illustrating a schematic configuration example of a vehicle control system.

FIG. 18 is an explanatory diagram illustrating an example of an installation position of an imaging section.

### MODE FOR CARRYING OUT THE INVENTION

Modes for carrying out the present technology (hereinafter, referred to as embodiments) will be described below. The description will be given in the following order.
1. First Embodiment (Example in which Wiring Lines are Covered with Voids)
2. Second Embodiment (Example in which Wiring Lines are Covered with Voids and Voids are Disposed in Resin)
3. Application Example to Mobile Body

### 1. First Embodiment

### Configuration Example of Semiconductor Element

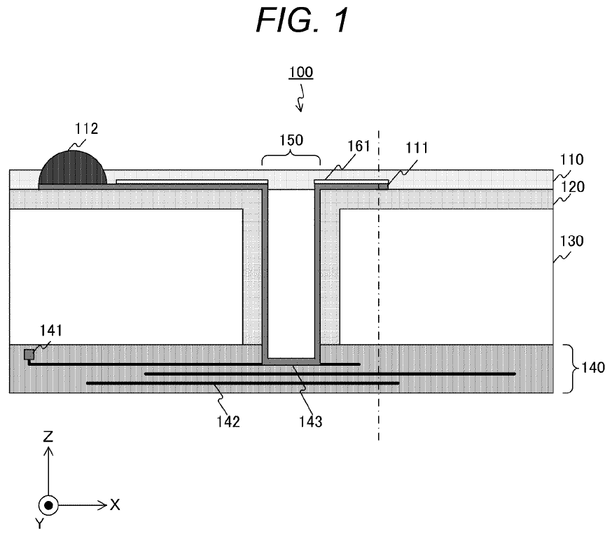

FIG. 1 is a cross-sectional view illustrating a configuration example of a semiconductor element 100 in a first embodiment of the present technology. The semiconductor element 100 is a semiconductor element provided in a wafer level chip size package (WCSP) or the like, and includes a protective resin film 110, a photosensitive insulating resin film 120, a semiconductor substrate 130, a wiring layer 140, and a through electrode 150. Examples of the semiconductor element 100 include a logic circuit, a memory, an image sensor, and an interposer.

The wiring layer 140 is formed on one of both surfaces of the semiconductor substrate 130. Hereinafter, out of both the surfaces of the semiconductor substrate 130, the surface on which the wiring layer 140 is formed is defined as a “front surface”, and a surface facing the front surface is defined as a “back surface”. In addition, a direction from the front surface to the back surface is defined as an “up” direction. The front surface can also be expressed as a lower surface, and the back surface can also be expressed as an upper surface. In the wiring layer 140, a built-in element 141, a predetermined number of wiring lines 142, and a pad 143 are disposed.

Hereinafter, an axis perpendicular to the front surface of the semiconductor substrate 130 is defined as a “Z axis”, and a predetermined axis parallel to the front surface of the semiconductor substrate 130 is defined as an “X axis”. An axis perpendicular to the X axis and the Y axis is defined as a “Y axis”. The figure is the cross-sectional view when viewed from a Y-axis direction.

The photosensitive insulating resin film 120 covers the back surface (in other words, the upper surface) of the semiconductor substrate 130. As the photosensitive insulating resin film 120, a photoresist of a negative tone development (NTD) type thermosetting organic film is used. In addition, as a material of the photosensitive insulating resin film 120, for example, polyimide, silicone, acrylic, epoxy, or a spin on carbon (SOC) material is used. Note that the photosensitive insulating resin film 120 is an example of an insulating film described in the claims.

The through electrode 150 is an electrode that penetrates the photosensitive insulating resin film 120 and the semiconductor substrate 130 and is connected to the pad 143. The through electrode 150 includes, for example, a through hole and wiring lines wired along a side surface of the through hole. In addition, the inside of the through electrode 150 is a cavity.

The protective resin film 110 covers an upper surface of the photosensitive insulating resin film 120. As the protective resin film 110, a photoresist of an NTD type thermosetting organic film is used. Note that the protective resin film 110 is an example of a protective film described in the claims.

In addition, in the protective resin film 110, a predetermined number of rewiring lines 111 are formed along the upper surface of the photosensitive insulating resin film 120. The protective resin film 110 can also be referred to as a redistribution layer (RDL). Examples of a material of the rewiring line 111 include titanium (Ti), copper (Cu), tantalum (Ta), nickel (Ni), tungsten (W), ruthenium (Ru), and cobalt (Co). Note that the rewiring line 111 is an example of a wiring line described in the claims.

In addition, each of the rewiring lines 111 is covered with a void 161. Note that the void 161 is an example of a covering void described in the claims.

In addition, an external connection terminal 112 (such as a bump) for connecting to the outside is disposed in the protective resin film 110. The external connection terminal 112 is connected to one end of any of the rewiring lines 111, and the other end of the rewiring line 111 is connected to the through electrode 150. The built-in element 141 in the wiring layer 140 is electrically connected to the external connection terminal 112 via the rewiring line 111 and the through electrode 150.

Here, inter-wiring capacitance C between a pair of adjacent rewiring lines 111 among the predetermined number of rewiring lines 111 is represented by the following expression.

$$C = ε S / d \qquad Expression 1$$

In the above expression, a unit of the inter-wiring capacitance C is, for example, farad (F). A dielectric constant is represented by F, and a unit thereof is, for example, farad per meter (F/m). An area of a side surface of the rewiring line is represented by S, and a unit thereof is, for example, square meters (m²). An interval between the wiring lines is represented by d, and a unit thereof is, for example, meters (m).

According to the above expression, as miniaturization proceeds, the interval d decreases and the inter-wiring capacitance increases. However, since wiring delay increases as the inter-wiring capacitance increases, it is important to reduce the inter-wiring capacitance in order to implement high-speed operation.

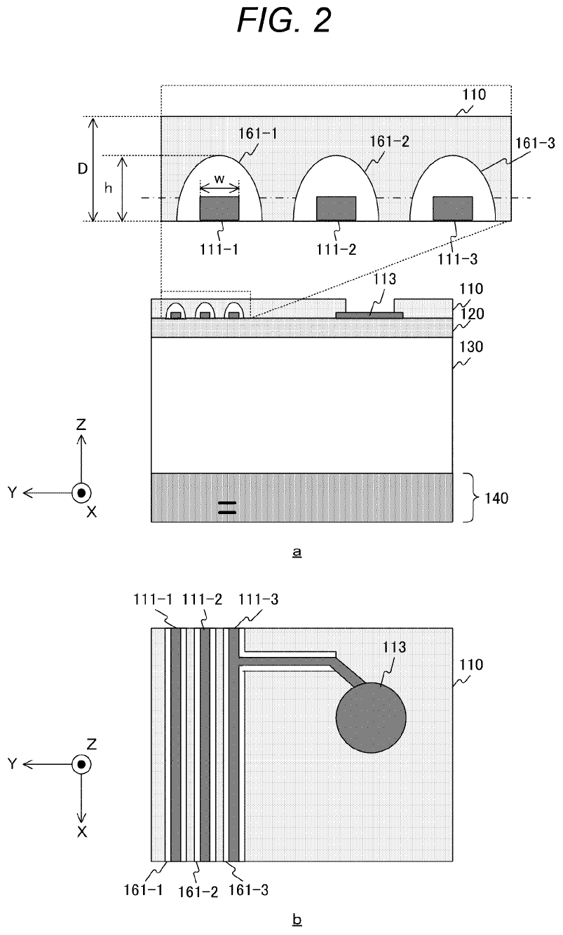

FIG. 2 is an example of a cross-sectional view and a plan view of the semiconductor element 100 in the first embodiment of the present technology. In FIG. 2, a is the cross-sectional view of the semiconductor element 100 taken along an alternate long and short dash line in FIG. 1 when viewed from an X-axis direction. In FIG. 2, b is the plan view of the semiconductor element 100 taken along an alternate long and short dash line in a in the figure when viewed from a Z-axis direction.

As illustrated in a in the figure, the plurality of rewiring lines 111 such as rewiring lines 111-1, 111-2, and 111-3 and the like is wired in the protective resin film 110. Each of these rewiring lines is covered with the void 161. The voids 161 covering the rewiring lines 111-1, 111-2, and 111-3 are defined as voids 161-1, 161-2, and 161-3, respectively.

It is assumed that each of the rewiring lines 111 is wired along the X axis. In this case, cross sections of the rewiring lines 111 are observed when viewed from the X-axis direction. In the cross sections, lower surfaces of the rewiring lines 111 are in seamless contact with the photosensitive insulating resin film 120, and upper surfaces and side surfaces thereof are covered with the voids 161.

Here, the dielectric constant F in Expression 1 is represented by the following expression.

$$ε = {ε}_{0} {ε}_{r} \qquad Expression 2$$

In the above expression, ε₀ is a vacuum dielectric constant, and Fr is a relative dielectric constant.

The relative dielectric constant εᵣ is, for example, about 3 for resin constituting the protective resin film 110, and is 1 for air. Therefore, according to Expression 2, in the configuration in which the upper surfaces and the side surfaces of the rewiring lines 111 are covered with the voids 161, the dielectric constant ε is smaller than that in the case where there is no void 161. When the dielectric constant ε decreases, the inter-wiring capacitance is reduced according to Expression 1.

As described in Patent Document 1, the inter-wiring capacitance can be reduced also by the method of disposing the void between the wiring lines. However, as illustrated in a in the figure, by covering the upper surfaces with the voids 161 in addition to the side surfaces, the inter-wiring capacitance can be reduced as compared with Patent Document 1.

In addition, when a size of the void 161 is too large, there is a concern that the protective resin film 110 may be recessed. Therefore, a height h of the void 161 from a boundary between the protective resin film 110 and the photosensitive insulating resin film 120 is preferably about ⅔ of a film thickness D of the protective resin film 110. Note that the height h can also be adjusted in accordance with a wiring width w of the rewiring line 111. For example, if the wiring width w is smaller than a predetermined value, the height h may exceed ⅔ of the film thickness D, and if the wiring width w is equal to or more than the predetermined value, the height h may be equal to or less than ⅔ of the film thickness D.

In addition, it is preferable that the void 161 covers each of the pair of adjacent rewiring lines 111 having different potentials. On the other hand, each of the pair of adjacent rewiring lines 111 having the same potential does not have to be covered with the void 161.

In addition, as illustrated in b in the figure, the rewiring line 111-3 is connected to a pad 113. In addition, when viewed from the Z-axis direction, each of the voids 161-1, 161-2, and 161-3 extends along the corresponding rewiring line 111.

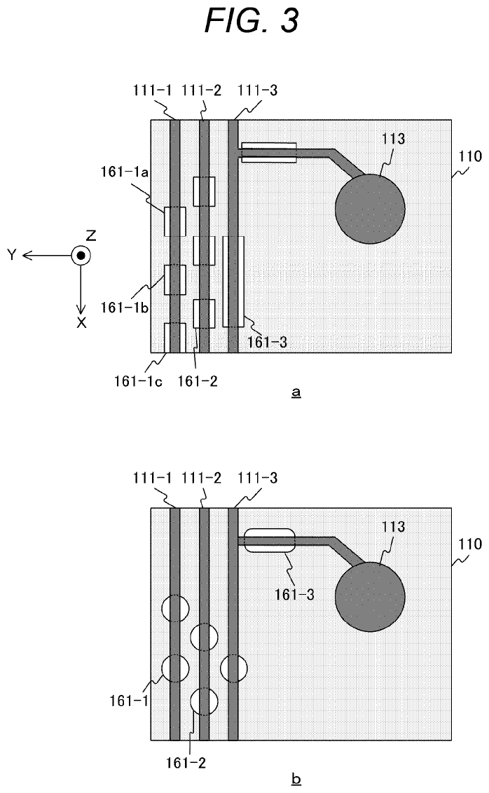

Note that, as illustrated in a of FIG. 3, the void 161 can be divided into a plurality of portions with different covering portions for each wiring line. For example, the void 161-1 is divided into three voids: a void 161-1a, a void 161-1b, and a void 161-1c.

In addition, in a in the figure, a shape of each portion obtained by dividing the void 161 is rectangular, but may be circular or elliptical as illustrated in b in the figure. The circular or elliptical void 161 can also be expressed as a hole. In addition, the rectangular void 161 can also be expressed as a trench.

### [Method for Manufacturing Semiconductor Element]

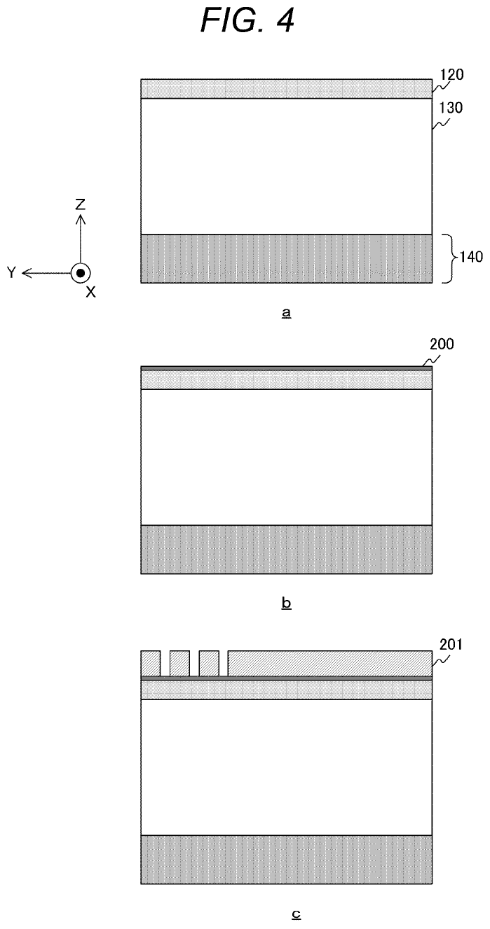

Subsequently, a method for manufacturing the semiconductor element 100 will be described with reference to FIGS. 4 to 6.

First, as illustrated in a of FIG. 4, the photosensitive insulating resin film 120 is formed on the back surface of the semiconductor substrate 130 by a spin coating method or the like. After a desired pattern is formed on the back surface by lithography, high temperature curing is performed.

Next, as illustrated in b in the figure, Cu or the like is deposited as a seed 200 on the upper surface of the photosensitive insulating resin film 120 by sputtering.

Next, as illustrated in c in the figure, a photoresist 201 is applied, and a pattern of the rewiring lines 111 is formed by the lithography.

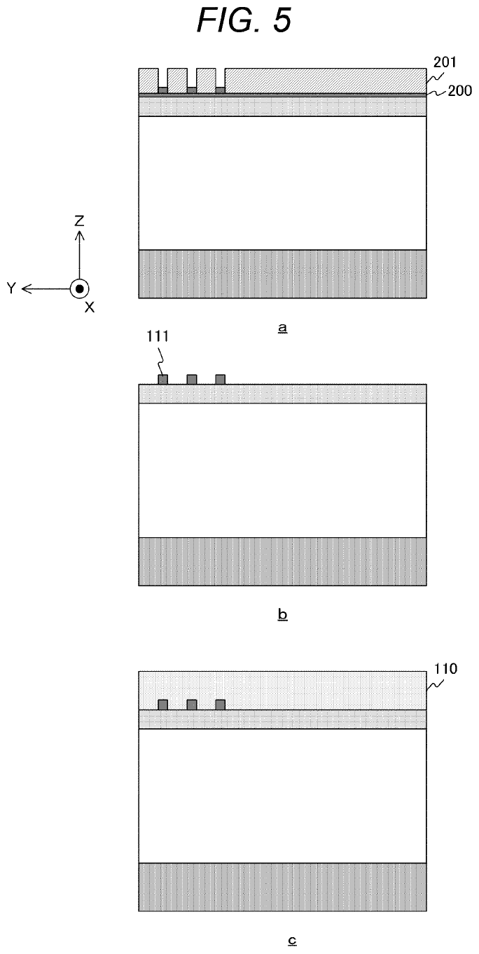

Then, as illustrated in a of FIG. 5, Cu is plated by electrolytic plating or electroless plating.

Next, as illustrated in b in the figure, the photoresist 201 is peeled off, and the seed 200 is removed by wet etching. With this arrangement, the rewiring lines 111 are formed.

Next, as illustrated in c in the figure, the protective resin film 110 is formed by the spin coating method or the like.

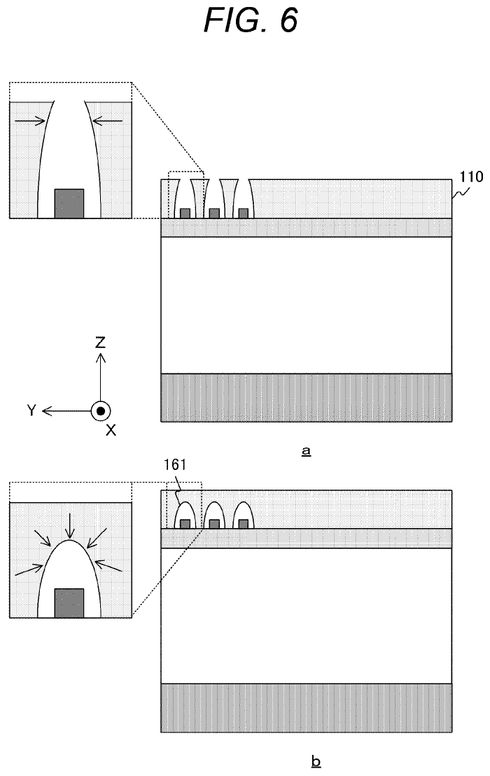

Then, as illustrated in a of FIG. 6, using a gray-tone mask (not illustrated), the lithography is performed on the protective resin film 110 with an exposure amount set to be relatively high. As described above, the protective resin film 110 is the NTD type resin. In this NTD type resin, when light is irradiated with the high exposure amount, a crosslinking reaction of an upper portion of the resin is promoted, and shrinkage occurs in a direction (direction of an arrow) in which upper portions of portions opened by the exposure are closed. At this time, since a dissolved matter is discharged by development, adjustment is performed so as not to cause complete closing.

Next, as illustrated in b in the figure, the high temperature curing is performed on the thermosetting protective resin film 110. At this time, the upper portions of the opened portions are closed by reflow, and the voids 161 are formed.

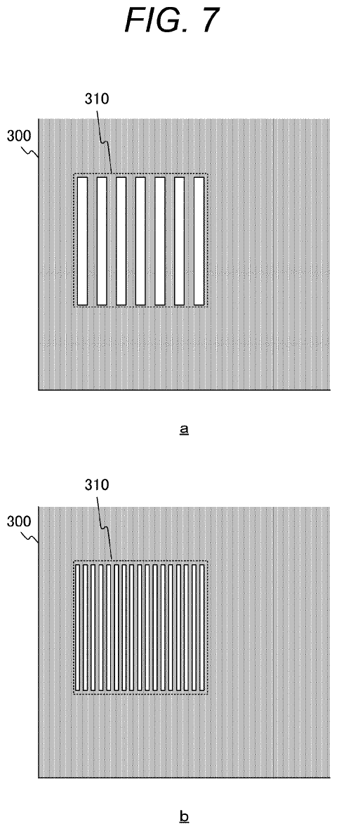

FIG. 7 is an example of a plan view of a gray-tone mask 300 in the first embodiment of the present technology. In the figure, a illustrates the gray-tone mask 300 used in the step in a of FIG. 6. A rectangular exposure area 310 is formed in the gray-tone mask 300. In the exposure area 310, strip-shaped transparent portions and strip-shaped light shielding portions are alternately arranged, and a stripe-shaped pattern is formed. White portions in the figure are the transparent portions, and glass or the like is used. Gray portions are the light shielding portions, and chromium (Cr) or the like is used.

Transmittance of the exposure area 310 can be adjusted by changing widths of the stripes in the exposure area 310.

For example, as illustrated in b of FIG. 7, by making the widths of the stripes narrower than those in a in the figure, the transmittance can be made lower than that in a in the figure. Thus, the exposure amount can be adjusted by changing the transmittance according to the pattern of the exposure area 310 of the gray-tone mask 300.

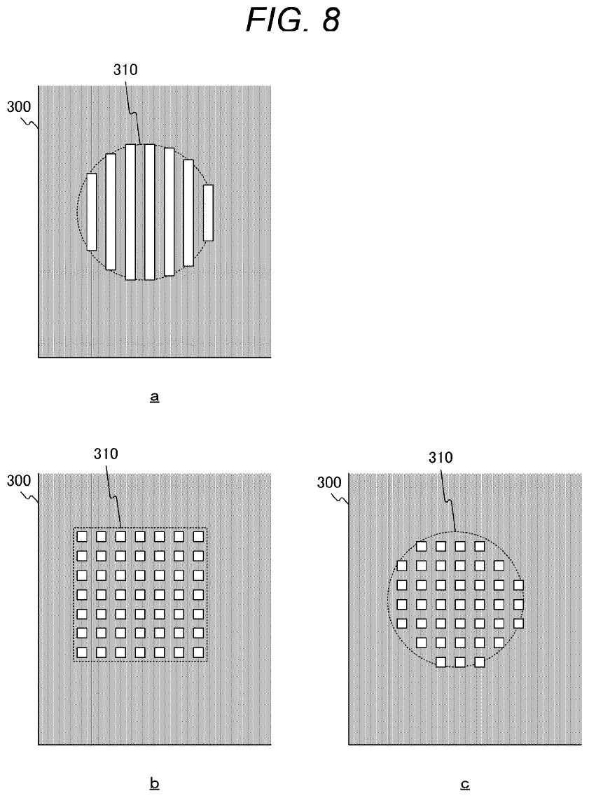

Note that, as illustrated in a of FIG. 8, the shape of the exposure area 310 is not limited to the rectangle, and may be a circle or the like.

In addition, as illustrated in b in the figure, the pattern of the exposure area 310 is not limited to the stripe shape, and may be a lattice shape. Even in the case of the lattice shape, as illustrated in c in the figure, the shape of the exposure area 310 is not limited to the rectangle, and may be a circle or the like.

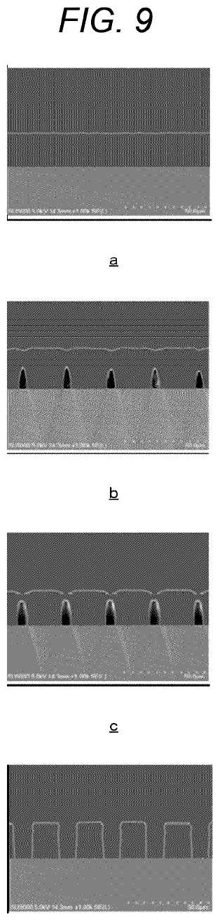

FIG. 9 is a view for describing a relationship between the transmittance and shapes of the voids in the first embodiment of the present technology. In the figure, a is an example of a photograph obtained by imaging, by a scanning electron microscope (SEM), a cross-sectional view of the semiconductor element 100 before the exposure.

In the figure, b is an example of a photograph obtained by imaging, by the SEM, the cross-sectional view when the transmittance of the gray-tone mask 300 is adjusted to 75% and the exposure is performed. In the figure, c is an example of a photograph obtained by imaging, by the SEM, the cross-sectional view when the transmittance of the gray-tone mask 300 is adjusted to 50% and the exposure is performed. In the figure, d is an example of a photograph obtained by imaging, by the SEM, the cross-sectional view when the transmittance of the gray-tone mask 300 is adjusted to 30% and the exposure is performed.

As illustrated in b, c, and d in the figure, the sizes of the voids 161 can be changed by adjusting the transmittance.

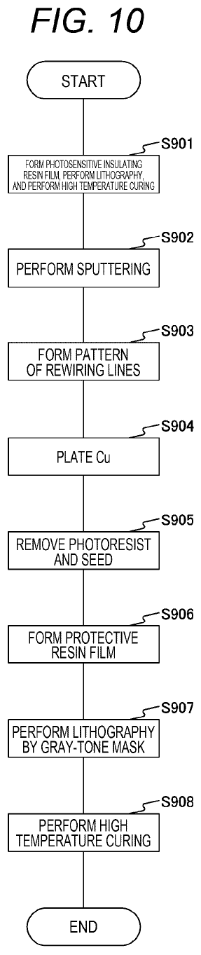

FIG. 10 is a flowchart indicating an example of the method for manufacturing the semiconductor element 100 in the first embodiment of the present technology. The photosensitive insulating resin film 120 is formed on the back surface of the semiconductor substrate 130, a desired pattern is formed by the lithography, and the high temperature curing is performed (step S901). Next, the seed 200 is deposited on the upper surface of the photosensitive insulating resin film 120 by the sputtering (step S902). Next, a pattern of the rewiring lines 111 is formed by the lithography (step S903).

Then, Cu is plated (step S904), and the photoresist 201 and the seed 200 are removed (step S905). Next, the protective resin film 110 is formed (step S906).

Then, the lithography is performed by the gray-tone mask (not illustrated) (step S907), and the high temperature curing is performed (step S908).

Thus, according to the first embodiment of the present technology, since the voids 161 covering the rewiring lines 111 are formed, the inter-wiring capacitance can be reduced.

### 2. Second Embodiment

In the first embodiment described above, the voids 161 covering the rewiring lines 111 are formed. However, in some cases, it is not possible to sufficiently suppress warpage of the semiconductor element 100 only by the voids 161. As described above, the photosensitive insulating resin film 120, the rewiring lines 111, and the protective resin film 110 are disposed between the semiconductor substrate 130 and the external connection terminal 112. In this case, there is a possibility that stress is applied to the semiconductor substrate 130 due to an expansion and contraction phenomenon of resin such as the photosensitive insulating resin film 120 or the like and metal such as the rewiring lines 111 or the like, and that the semiconductor element 100 and a wafer including the semiconductor element 100 are warped. An influence of the warpage is remarkable in particular in the large-diameter semiconductor element 100, and mitigation of the stress is important for suppressing the warpage. A semiconductor element 100 in a second embodiment is different from that of the first embodiment in that voids are added to a photosensitive insulating resin film 120 and the like to mitigate stress.

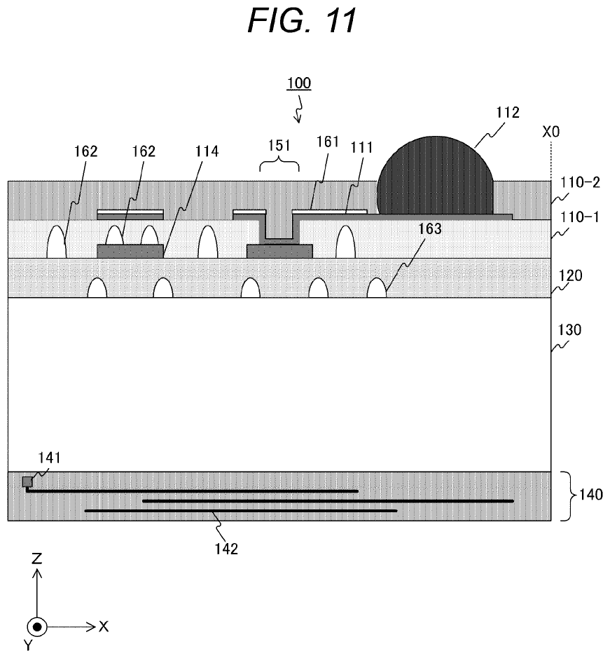

FIG. 11 is a cross-sectional view illustrating a configuration example of the semiconductor element 100 in the second embodiment of the present technology. The semiconductor element 100 in the second embodiment is different from that of the first embodiment in that a protective resin film 110 has two layers and voids 162 and 163 are further formed.

Out of the two layers of the protective resin film 110, an upper side is defined as a protective resin film 110-2, and a lower side is defined as a protective resin film 110-1. Rewiring lines 111 and an external connection terminal 112 are formed on the protective resin film 110-2 on the upper side. Rewiring lines 114 are formed on the protective resin film 110-1 on the lower side, and are electrically connected to the rewiring lines 111 on the upper side by a through electrode 151.

The voids 162 are formed in the protective resin film 110-1 on the lower side. Note that the protective resin film 110-1 is an example of a first protective film described in the claims, and the protective resin film 110-2 is an example of a second protective film described in the claims. The void 162 is an example of an intra-protective film void described in the claims.

In addition, the voids 163 are formed in the photosensitive insulating resin film 120. Note that the void 163 is an example of an intra-insulating film void described in the claims.

Note that, in the figure, the voids 162 and the voids 163 are disposed in both the protective resin film 110-1 and the photosensitive insulating resin film 120. However, it is also possible to dispose only one of the voids 162 and the voids 163 in one of the protective resin film 110-1 and the photosensitive insulating resin film 120.

As illustrated in the figure, by disposing the voids 162 and the voids 163 in the protective resin film 110-1 and the photosensitive insulating resin film 120, a volume of resin can be reduced and the stress can be mitigated. With this arrangement, warpage of the semiconductor element 100 and a wafer can be suppressed.

There is no limitation on portions where the voids 162 and 163 are disposed. However, for example, it is preferable to preferentially dispose the voids 162 and 163 in a central portion of the semiconductor element 100 or the wafer to which the stress is likely to be locally applied. Note that it is preferable not to form the voids 162 or the voids 163 in the vicinity of a lower portion of the external connection terminal 112 to which external stress is applied. In addition, it is preferable not to form the voids 162 or the voids 163 in the vicinity of an end portion (for example, a coordinate X0) of the semiconductor element 100. This is because stress is applied to the end portion when the semiconductor element 100 is cut out from the wafer, and the end portion is prevented from being recessed by the stress.

The voids 162 and 163 are also formed by lithography using a gray-tone mask 300 as in the first embodiment. By selectively changing transmittance of the gray-tone mask 300, the voids 162 and the like can be simultaneously formed at a plurality of portions having different steps. For example, in the figure, the voids 162 are simultaneously formed in each of an upper portion of the rewiring line 114 and the other portions.

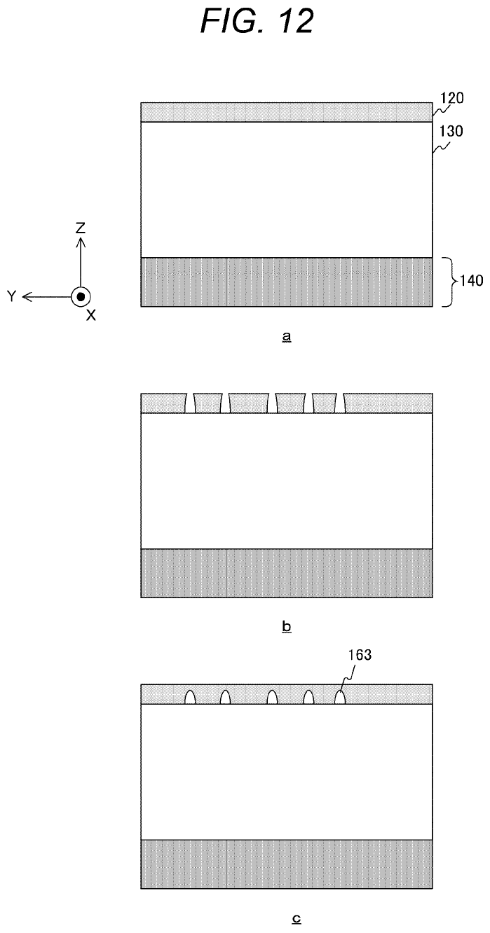

Subsequently, a method for manufacturing the semiconductor element 100 in the second embodiment will be described with reference to FIGS. 12 to 16.

First, as illustrated in a of FIG. 12, the photosensitive insulating resin film 120 is formed on a back surface of a semiconductor substrate 130 by a spin coating method or the like. Next, as illustrated in b in the figure, using the gray-tone mask (not illustrated), the lithography is performed with an exposure amount set to be relatively high. Next, as illustrated in c in the figure, the high temperature curing is performed, and the voids 163 are formed in the photosensitive insulating resin film 120 by the reflow.

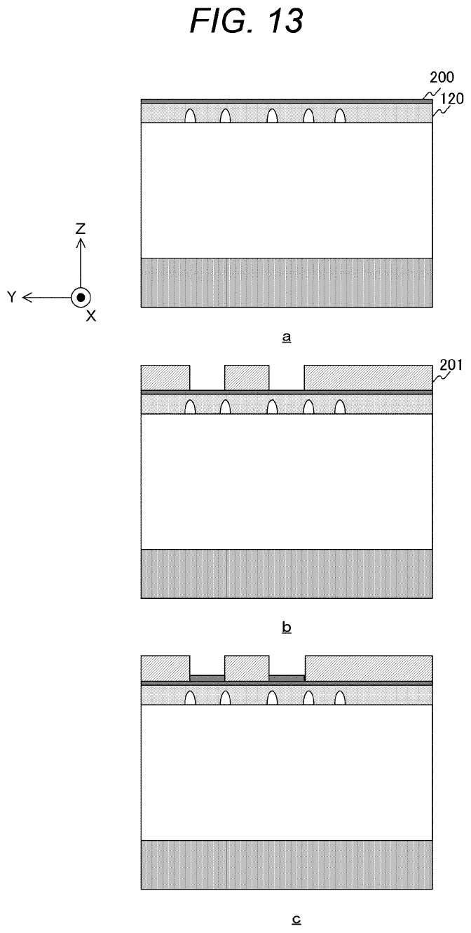

Then, as illustrated in a in FIG. 13, Cu or the like is deposited as a seed 200 on an upper surface of the photosensitive insulating resin film 120 by the sputtering. Next, as illustrated in b in the figure, a photoresist 201 is applied, and a pattern of the rewiring lines 114 on a lower side is formed by the lithography. Next, as illustrated in c in the figure, Cu is plated by electrolytic plating or electroless plating.

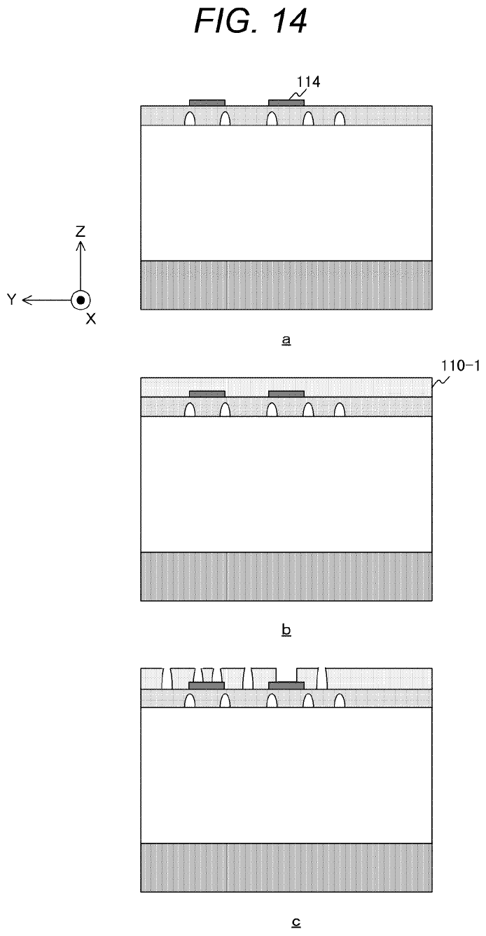

Then, as illustrated in a in FIG. 14, the photoresist 201 is peeled off, and the seed 200 is removed by the wet etching. With this arrangement, the rewiring lines 114 are formed. As illustrated in b in the figure, the protective resin film 110-1 is formed on the upper surface of the photosensitive insulating resin film 120 by the spin coating method or the like. Next, as illustrated in c in the figure, using the gray-tone mask (not illustrated), the lithography is performed with an exposure amount set to be relatively high.

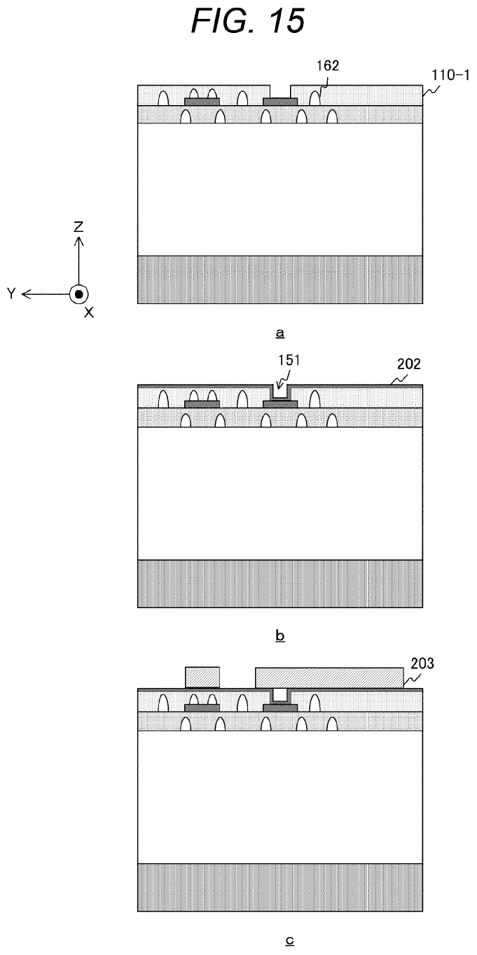

Then, as illustrated in a of FIG. 15, high temperature curing is performed, and the void 162 is formed in the protective resin film 110-1 by reflow. Next, as illustrated in b in the figure, Cu or the like is deposited as a seed 202 on an upper surface of the protective resin film 110-1 by sputtering. Next, as illustrated in c in the figure, a photoresist 203 is applied, and a pattern of the rewiring lines 111 on an upper side is formed by the lithography.

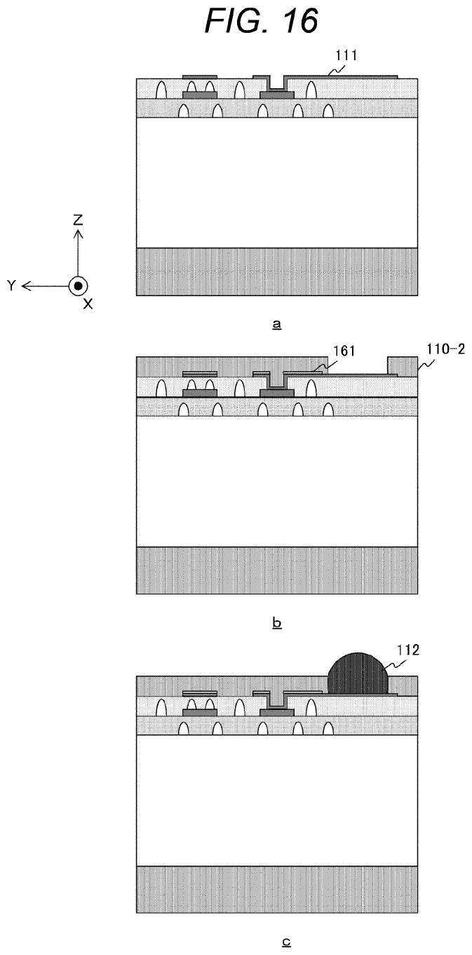

Then, as illustrated in a in FIG. 16, the photoresist 203 is peeled off, and the seed 202 is removed by wet etching. With this arrangement, the rewiring lines 111 on the upper side are formed. Next, as illustrated in b in the figure, the protective resin film 110-2 is formed on the upper surface of the protective resin film 110-1 by the spin coating method or the like. In addition, voids 161 are formed by the lithography using the gray-tone mask (not illustrated) and the high temperature curing. Next, as illustrated in c in the figure, the external connection terminal 112 is formed.

Thus, according to the second embodiment of the present technology, since the voids 162 and the voids 163 are disposed in the protective resin film 110-2 and the photosensitive insulating resin film 120, the stress can be mitigated. With this arrangement, warpage of the semiconductor element 100 and the wafer can be suppressed.

### 3. Application Example to Mobile Body

The technology according to the present disclosure (present technology) can be applied to various kinds of products. For example, the technology according to the present disclosure may be implemented as a device included in any type of mobile body such as an automobile, an electric vehicle, a hybrid electric vehicle, a motorcycle, a bicycle, a personal mobility, an airplane, a drone, a ship, a robot, and the like.

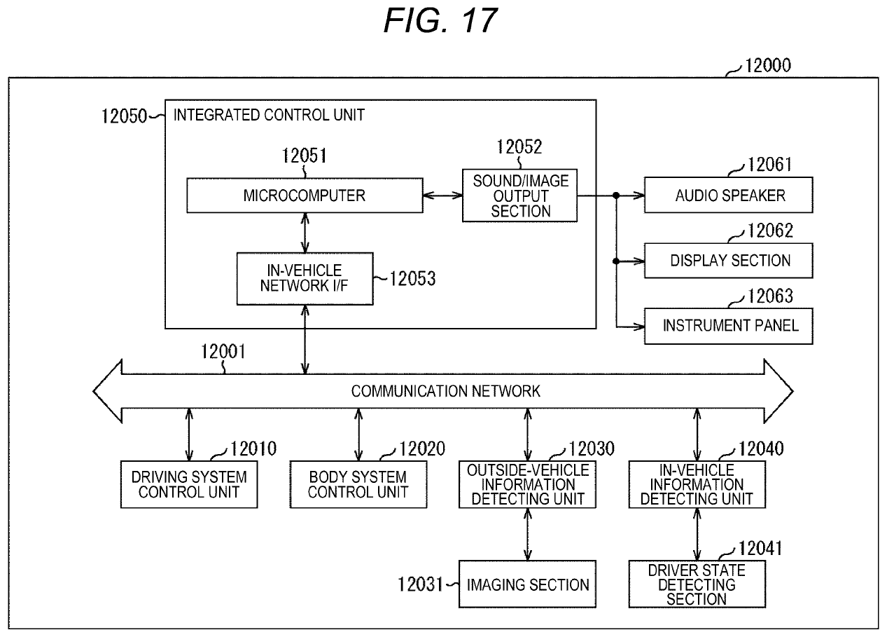

FIG. 17 is a block diagram illustrating a schematic configuration example of a vehicle control system as an example of a mobile body control system to which the technology according to the present disclosure can be applied.

The vehicle control system 12000 includes a plurality of electronic control units connected to each other via a communication network 12001. In the example illustrated in FIG. 17, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and an in-vehicle network interface (I/F) 12053 are illustrated as functional configurations of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example in FIG. 17, as the output device, an audio speaker 12061, a display section 12062, and an instrument panel 12063 are illustrated. The display section 12062 may, for example, include at least one of an on-board display and a head-up display.

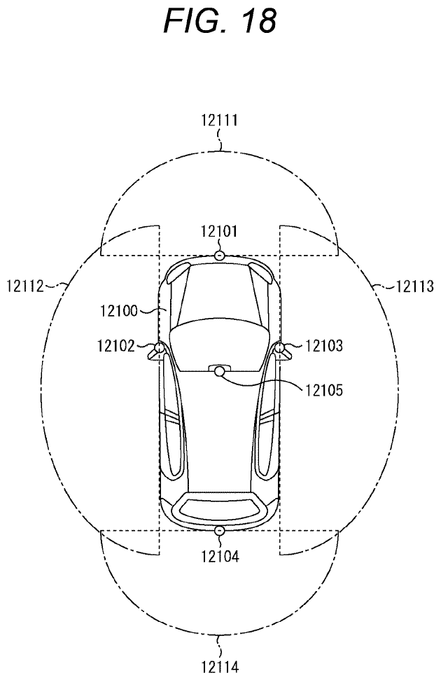

FIG. 18 is a diagram illustrating an example of an installation position of the imaging section 12031.

In FIG. 18, imaging sections 12101, 12102, 12103, 12104, and 12105 are included as the imaging section 12031.

The imaging sections 12101, 12102, 12103, 12104, and 12105 are, for example, provided at positions on a front nose, sideview mirrors, a rear bumper, and a back door of a vehicle 12100 as well as a position on an upper portion of a windshield in the interior of the vehicle, or the like. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly images of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 18 illustrates examples of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to, for example, the imaging section 12031 among the configurations described above. Specifically, the semiconductor element 100 in FIG. 1 can be applied to the imaging section 12031. By applying the technology according to the present disclosure to the imaging section 12031, the inter-wiring capacitance can be reduced and the high-speed operation can be performed.

Note that the embodiments described above indicate examples for embodying the present technology, and the respective matters in the embodiments and the respective matters specifying the invention in the claims have correspondence relationships. Similarly, the respective matters specifying the invention in the claims and the respective matters with the same names in the embodiments of the present technology have correspondence relationships. Note that the present technology is not limited to the embodiments, and can be embodied by applying various kinds of modification to the embodiments without departing from the scope of the present technology.

Note that, the effects described in the present specification are merely examples and are not limited, and other effects may also be achieved.

Note that the present technology can also have the following configurations.

(1) A semiconductor element including:
a semiconductor substrate;
an insulating film that covers a predetermined surface of the semiconductor substrate;
a protective film that covers the insulating film;
a predetermined number of wiring lines formed in the protective film; and
a covering void that includes a void that covers each of the wiring lines in the protective film.

(2) The semiconductor element according to (1), further including
an intra-insulating film void that includes a void formed in the insulating film.

(3) The semiconductor element according to (2), further including
an intra-protective film void that includes a void formed in the protective film,
in which the protective film includes:
a first protective film that covers the insulating film; and
a second protective film that covers the first protective film, and
the intra-protective film void is formed in the first protective film.

(4) The semiconductor element according to (3), further including
an external connection terminal connected to the wiring line,
in which the intra-insulating film void and the intra-protective film void are disposed so as to avoid the vicinity of the external connection terminal.

(5) The semiconductor element according to (3) or (4), in which
the intra-insulating film void and the intra-protective film void are disposed so as to avoid the vicinity of an end portion of the semiconductor element.

(6) The semiconductor element according to any one of (3) to (5), in which
the intra-insulating film void and the intra-protective film void are preferentially disposed in a central portion of the semiconductor element.

(7) The semiconductor element according to any one of (1) to (6), in which
the predetermined number of wiring lines include a pair of wiring lines that have different potentials, and
the covering void covers each of the pair of wiring lines.

(8) The semiconductor element according to any one of (1) to (7), in which
the covering voids extend along the wiring lines when viewed from a direction perpendicular to the predetermined surface.

(9) The semiconductor element according to any one of (1) to (8), in which
contact surfaces of the wiring lines are in contact with the insulating film, and
the covering voids cover other than the contact surface when viewed from a direction parallel to the predetermined surface.

(10) The semiconductor element according to any one of (1) to (9), in which
the covering void has any one of a rectangular shape, a circular shape, and an elliptical shape when viewed from a direction perpendicular to the predetermined surface.

(11) The semiconductor element according to any one of (1) to (10), in which
a material of the insulating film includes any one of polyimide, silicone, acrylic, epoxy, and a spin on carbon (SOC) material.

(12) The semiconductor element according to any one of (1) to (11), in which
the semiconductor element includes any one of a logic circuit, a memory, an image sensor, and an interposer.

(13) A method for manufacturing a semiconductor element, the method including:
an insulating film formation procedure of forming an insulating film on a predetermined surface of a semiconductor substrate;
a wiring procedure of forming a predetermined number of wiring lines;
a protective film formation procedure of forming a protective film that protects each of the wiring lines; and
a void formation procedure of forming, in the protective film, a covering void that includes a void that covers each of the wiring lines.

(14) The method for manufacturing according to (13), in which
the protective film includes a negative tone development (NTD) type thermosetting photoresist, and
the void formation procedure includes:
a lithography procedure of performing lithography on the protective film using a predetermined gray-tone mask; and
a curing procedure of performing curing on the protective film.

### REFERENCE SIGNS LIST

100 Semiconductor element
110, 110-1, 110-2 Protective resin film
111, 111-1, 111-2, 111-3, 114 Rewiring line
112 External connection terminal
113 Pad
120 Photosensitive insulating resin film
130 Semiconductor substrate
140 Wiring layer
141 Built-in element
142 Wiring line
143 Pad
150, 151 Through electrode
161, 161-1, 161-1a, 161-1b, 161-1c, 161-2, 161-3, 162, 163 Void
200, 202 Seed
201, 203 Photoresist
300 Gray-tone mask
310 Exposure area
12031 Imaging section

What is claimed is:

1. A semiconductor element, comprising:
a semiconductor substrate;
an insulating film that covers a predetermined surface of the semiconductor substrate;
a protective film that covers the insulating film;
a predetermined number of wiring lines formed in the protective film; and
a covering void that includes a void that covers each of the wiring lines in the protective film.

2. The semiconductor element according to claim 1, further comprising
an intra-insulating film void that includes a void formed in the insulating film.

3. The semiconductor element according to claim 2, further comprising
an intra-protective film void that includes a void formed in the protective film,
wherein the protective film includes:
a first protective film that covers the insulating film; and
a second protective film that covers the first protective film, and
the intra-protective film void is formed in the first protective film.

4. The semiconductor element according to claim 3, further comprising
an external connection terminal connected to the wiring line,
wherein the intra-insulating film void and the intra-protective film void are disposed so as to avoid a vicinity of the external connection terminal.

5. The semiconductor element according to claim 3, wherein
the intra-insulating film void and the intra-protective film void are disposed so as to avoid a vicinity of an end portion of the semiconductor element.

6. The semiconductor element according to claim 3, wherein
the intra-insulating film void and the intra-protective film void are preferentially disposed in a central portion of the semiconductor element.

7. The semiconductor element according to claim 1, wherein
the predetermined number of wiring lines include a pair of wiring lines that have different potentials, and
the covering void covers each of the pair of wiring lines.

8. The semiconductor element according to claim 1, wherein
the covering voids extend along the wiring lines when viewed from a direction perpendicular to the predetermined surface.

9. The semiconductor element according to claim 1, wherein
contact surfaces of the wiring lines are in contact with the insulating film, and
the covering voids cover other than the contact surface when viewed from a direction parallel to the predetermined surface.

10. The semiconductor element according to claim 1, wherein
the covering void has any one of a rectangular shape, a circular shape, and an elliptical shape when viewed from a direction perpendicular to the predetermined surface.

11. The semiconductor element according to claim 1, wherein
a material of the insulating film includes any one of polyimide, silicone, acrylic, epoxy, and a spin on carbon (SOC) material.

12. The semiconductor element according to claim 1, wherein
the semiconductor element includes any one of a logic circuit, a memory, an image sensor, and an interposer.

13. A method for manufacturing a semiconductor element, the method comprising:
an insulating film formation procedure of forming an insulating film on a predetermined surface of a semiconductor substrate;
a wiring procedure of forming a predetermined number of wiring lines;
a protective film formation procedure of forming a protective film that protects each of the wiring lines; and
a void formation procedure of forming, in the protective film, a covering void that includes a void that covers each of the wiring lines.

14. The method for manufacturing according to claim 13, wherein
the protective film includes a negative tone development (NTD) type thermosetting photoresist, and
the void formation procedure includes:
a lithography procedure of performing lithography on the protective film using a predetermined gray-tone mask; and
a curing procedure of performing curing on the protective film.
